(19) United States
(12) Patent Application Publication
(10) Pub. No.: US 2018/0204508 A1
(43) Pub. Date: Jul. 19, 2018

(54) OLED PWM DRIVING METHOD

(71) Applicant: Shenzhen China Star Optoelectronics Technology Co., Ltd., Shenzhen (CN)

(72) Inventors: Mingfeng Chen, Shenzhen (CN); Ming Jong Jou, Shenzhen (CN); Chih Hao Wu, Shenzhen (CN)

(21) Appl. No.: 15/328,527

(22) PCT Filed: Jan. 6, 2017
(86) PCT No.: PCT/CN2017/070417

§ 371 Date: Jul. 7, 2017

(30) Foreign Application Priority Data
Aug. 25, 2016 (CN) 201610719851.0

(51) Int. Cl. G09G 3/3208; H01L 27/32

(52) U.S. Cl. CPC G09G 3/3208; G09G 2310/0264; H01L 27/3244

(57) ABSTRACT

Disclosed is an OLED PWM driving method, including: dividing each input frame of image into an equal number of subfields with a same size; and changing each subfield dynamically by adjusting a time for lighting the subfield, such that the gray-scales displayed become smoother.

### CROSS-REFERENCE TO RELATED APPLICATIONS

The present application claims the priority of Chinese patent application CN201610719851.0, entitled “OLED PWM driving method” and filed on Aug. 25, 2015, the entirety of which is incorporated herein by reference.

### FIELD OF THE INVENTION

The present disclosure relates to the technical field of control of an organic display, and in particular, to an OLED PWM driving method.

### BACKGROUND OF THE INVENTION

FIG. 1 shows an OLED (Organic Light Emitting Diode) 3T1C (3 transistors, T1, T2, T3, 1 capacitance Cst) pixel driving circuit, in which D denotes a data driving signal, G denotes a charging scan signal, DG denotes a discharge scan signal, ODdd denotes a constant-current driving signal, and Ovss denotes an OLED output voltage. When the circuit is driven digitally, only two Gamma voltage levels are output at V_{A}, i.e., two voltage levels of GM1 (brightest) and GM9 (darkest). The following is a current-voltage I-V equation for a transistor:

I_{ds,sat}=k·(V_{GS}−V_{th,T2})²=k·(V_{A}−V_{S}−V_{th,T2})²

wherein, I_{ds,sat} is a conduction current of the transistor, k is an intrinsic conductivity factor, V_{GS} is a gate-source voltage of the transistor, V_{th,T2} is a threshold voltage for a transistor T2, V_{A} represents a voltage at point V_{A}, and V_{S} represents a voltage at point V_{S}. Due to degradation or non-uniformity of the component, variation ΔVth in the threshold voltage Vth of the transistor is smaller than variation of (VA-VS). Therefore, compared to an analog driving method, a digital driving method can help to alleviate uneven brightness of an OLED.

When the pixel driving circuit shown in FIG. 1 is operated, a transistor T1 charges the circuit and enables the voltage at point VA to be increased, and a transistor T3 discharges the circuit and enables the voltage at the point VA to be decreased. As a result, the VA point is controlled to output only two Gamma voltage levels, and to output gray-scales by means of PWM (Pulse-Width Modulation).

By controlling a length of a charging time for a subfield SF of a frame of image, combined with a principle that perception of the brightness by human eyes is integration over time, digital voltages (i.e., two Gamma voltages) may be utilized to display images with brightness of various gray-scales. FIG. 2 shows a driving schematic diagram for a structure as shown in FIG. 1, in which a slash 1 denotes a charging scan process for a pixel within a subfield (the transistor T1), a slash 2 denotes a discharging scan process for a pixel within a subfield (the transistor T3), a light-colored region denotes a process for lighting a corresponding a pixel within a subfield (turning on the transistor T2), and a dark-colored region denotes a process for turning off a pixel (turning off the transistor T2). Tcharge represents a time required for charging scan an image, and Tdischarge represents a time required for discharging scan an image.

FIGS. 3a-3c schematically show successive frames of images displayed by an OLED 3T1C driving circuit under PWM 6 bit digital driving condition. Scan time periods for 6 subfields corresponding to bit1-bit6 in each frame of image are the same, and outputs are in an order of bit6 to bit 1. Advantages of such digital driving method lie in that sizes of 6 subfields corresponding to each frame are the same and since outputs are in an order of bit6 to bit 1, it is easy to implement driving. Defects of such digital driving method lie in that since driving voltages D are different from frame to frame, integral effects are different (for example, bit3-bit1 for a (N−1)^{th} frame and bit6-bit4 for a N^{th} frame produce new integral effects), which causes flicker images and steps appeared in successive gray-scales, resulting in poor display effect.

### SUMMARY OF THE INVENTION

In order to solve the above problem, the present disclosure provides an OLED PWM driving method, to eliminate the problem of flicker images and step effects in displayed gray-scales in the existing OLED PWM driving design solution.

The present disclosure, in an embodiment thereof, provides an OLED PWM driving method, including:

dividing each input frame of image into an equal number of subfields with a same size; and

changing each subfield dynamically by adjusting a time for lighting the subfield, such that the gray-scales displayed become smoother.

According to an embodiment of the present disclosure, changing each subfield dynamically by adjusting the time for lighting the subfield further includes:

determining a subfield reference time for lighting pixels in each subfield after the frame of image is divided; and

adding a corresponding minor adjustment value on the subfield reference time for lighting pixels in each subfield, to adjust the time length for lighting the subfield.

According to an embodiment of the present disclosure, the subfield reference time is a time for lighting pixels in a subfield of any frame of image.

According to an embodiment of the present disclosure, the minor adjustment value is a time difference between a time for lighting pixels in a subfield of a frame of image, and a time for lighting pixels in a corresponding subfield of a frame of image, which is taken as the subfield reference time.

According to an embodiment of the present disclosure, the minor adjustment value is smaller than the subfield reference time taken as the reference time of a corresponding subfield of the frame of image.

According to an embodiment of the present disclosure, the minor adjustment values satisfy:

Σₙ₌₁^{N}(a₁+a₂+ . . . +a_{N})=0

wherein, a₁, a₂ . . . a_{N} represents minor adjustment values over subfield reference times for corresponding subfields in the first, second, . . . , N^{th} frame of images, and N is the number of the frames of images.

According to an embodiment of the present disclosure, at the same time each subfield is changed dynamically by adjusting the time for lighting the subfield, the distribution of the subfields in the frame of image is adjusted to smooth the displayed gray-scales.

According to an embodiment of the present disclosure, by adjusting an output order of the subfields in the same frame of image, the distribution of the subfields in the same frame of image is adjusted.

According to an embodiment of the present disclosure, adjusting the distribution of the subfields in the same frame of image by adjusting the output order of the subfields in the same frame of image further includes: setting the output orders of the subfields in two adjacent frames of images to be the same.

According to an embodiment of the present disclosure, adjusting the distribution of the subfields in the same frame of image by adjusting the output order of the subfields in the same frame of image further includes: setting the output orders of the subfields in two adjacent frames of images to be different.

The present disclosure has the following advantageous effects.

In the present disclosure, each subfield is changed dynamically by adjusting time length for lighting the subfield, by way of which the displayed gray-scales by PWM OLED becomes smoother, the displayed image is better, and the problems of flicker images and step effects in displayed gray-scales in the existing OLED PWM driving design solution are eliminated.

Other advantages, objectives and features of the present disclosure will be partly set forth in the following description, and will partly become apparent for those skilled in the art from study of the following description, or will be learned from practice of the present disclosure. The objectives and other advantages of the present disclosure will be realized and achieved through the structures specifically pointed out in the following description, claims, and the accompanying drawings.

### BRIEF DESCRIPTION OF THE DRAWINGS

The drawings are provided for further understanding of the present disclosure, and constitute one part of the description. The drawings of embodiments of the present disclosure serve to explain the technical solution of the present disclosure in conjunction with the embodiments of the present disclosure, rather than to limit the present disclosure in any manner. In the drawings:

FIG. 1 schematically shows an OLED 3T1C pixel driving circuit in the prior art;

FIG. 2 schematically shows an image corresponding to a 6-subfield PWM driving condition as shown in FIG. 1;

FIGS. 3a-3c schematically show successive frames of images corresponding to a 6-subfield PWM driving condition as shown in FIG. 1;

FIG. 4 is a flowchart for a method according to an embodiment of the present disclosure;

FIGS. 5a-5c schematically show a 4-subfield OLED PWM driving according to an embodiment of the present disclosure; and

FIG. 6 schematically shows the 4-subfield OLED PWM digital driving with orders and sizes of subfields being adjusted according to an embodiment of the present disclosure.

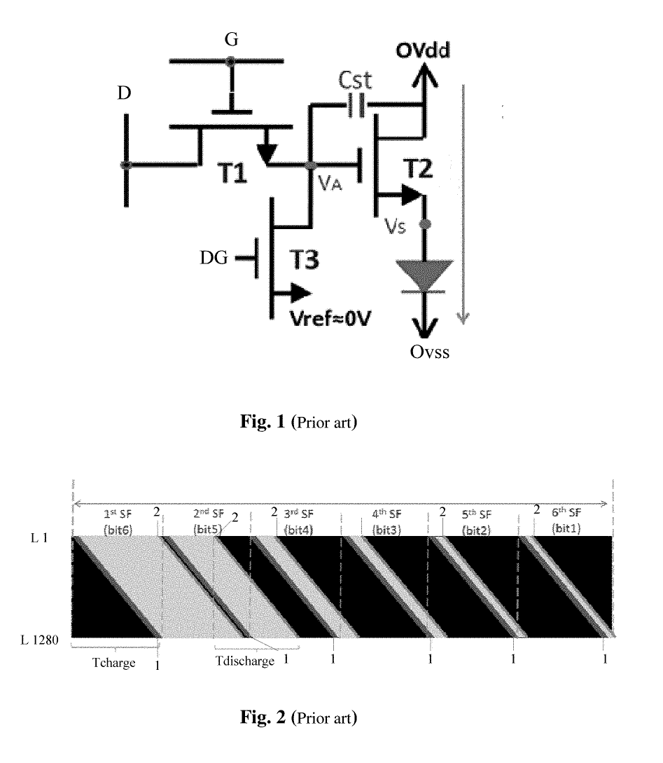

### DETAILED DESCRIPTION OF THE EMBODIMENTS

Implementations of the present disclosure will be described in detail with reference to the accompanying drawings and embodiments, thereby how the technical solutions are applied in the present disclosure to solve the technical problems to achieve corresponding technical effects can be fully understood and practiced accordingly. Embodiments of the present disclosure and various features in the embodiments may be combined with each other without conflict, and the resulting technical solutions are all within the scope of the present disclosure.

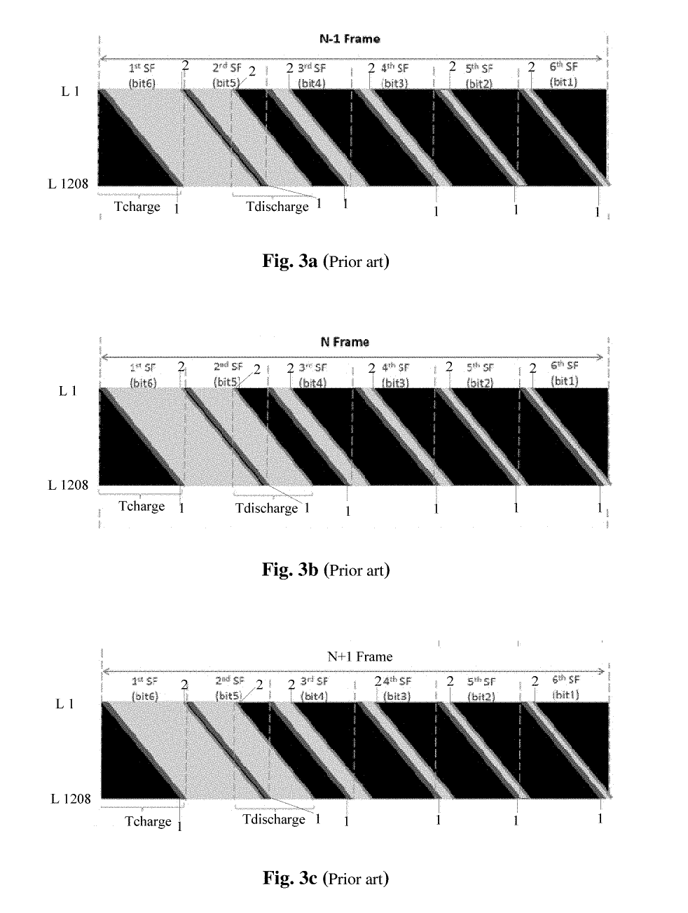

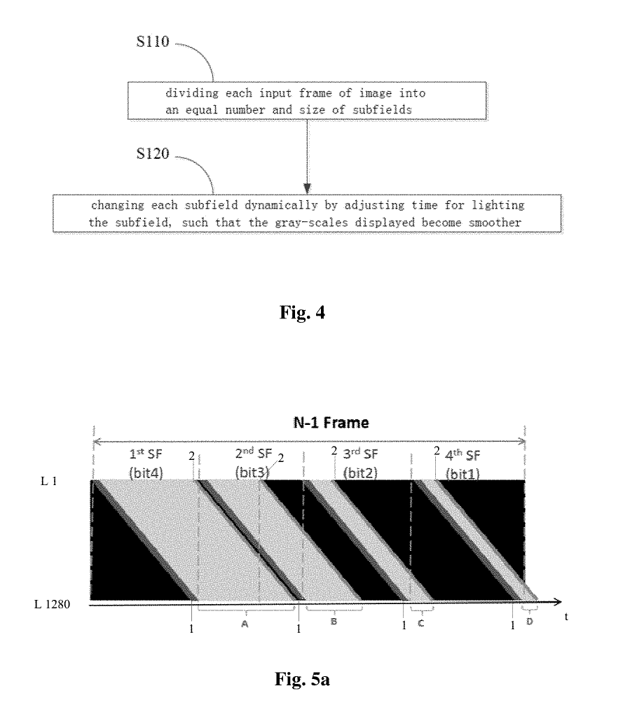

In order to solve the problem of flicker images and steps appeared in successive gray-scales caused by different digital driving signals D and thus different integral effects from frame to frame as shown in FIG. 3, the present disclosure provides an OLED PWM driving method. FIG. 4 shows a flowchart of a method according to an embodiment of the present disclosure. Hereinafter, the present disclosure will be described in detail with reference to FIG. 4.

Specifically, the OLED PWM driving method includes two steps. Firstly, at step S110, each input frame of image is divided into an equal number of subfields with a same size. Next, at step S120, each subfield is changed dynamically by adjusting time for lighting the subfield, such that the gray-scales displayed become smoother. Specifically, each frame of image is divided into an equal number of subfields with a same size and the plurality of subfields is outputted in a certain order. It is possible to divide each frame of image into 6 subfields having a same size, and the subfields of each frame of image are outputted in an order of bit6-bit1, similar to the method as shown in FIG. 2. By adjusting the time length for lighting each subfield, the gray-scale displayed for the subfield can be changed. Thus, the displayed gray-scales can be smoother, solving the problem of flicker images and steps in successive gray-scales, resulting in improved display effect.

In an embodiment of the present disclosure, the step of changing each subfield dynamically by adjusting a time length for lighting the subfield, further including:

determining a subfield reference time for lighting pixels in each subfield after the frame of image is divided; and adding a corresponding minor adjustment value on the subfield reference time for lighting pixels in each subfield, to adjust the time length for lighting the subfield. Specifically, any frame of image may be selected as a reference, and a time for lighting pixels in each subfield after the frame of image is divided may be selected as the subfield reference time for a corresponding subfield of other frames of images. The minor adjustment value may be selected as a time difference between a time for lighting pixels in a subfield of a frame of image, and a time for lighting pixels in a corresponding subfield of a frame of image, which is taken as the subfield reference time.

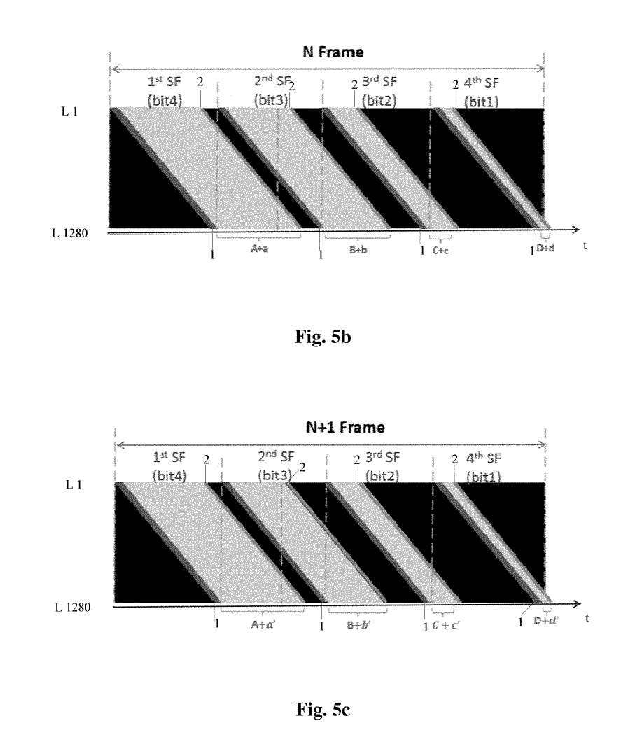

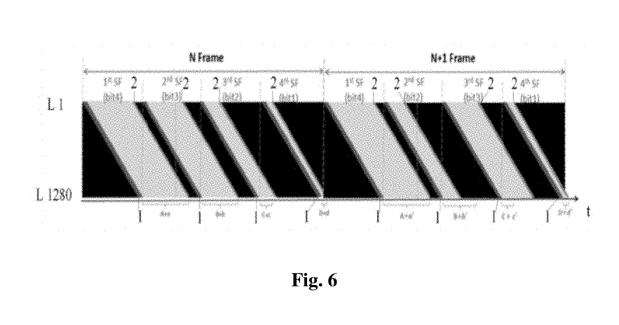

Referring to FIGS. 5a-5c, OLED PWM driving with 4 subfields will be illustrated as an example. As shown in FIGS. 5a-5c, in a (N−1)^{th} frame of image, a lighting time for a pixel in a first subfield bit4 is A. A lighting time for a pixel in a second subfield bit3 is B. A lighting time for a pixel in a third subfield bit2 is C. A lighting time for a pixel in a fourth subfield bit1 is D. The corresponding subfield reference times are successively A, B, C and D.

As shown in FIG. 5b, in a N^{th} frame of image, lighting times for a pixel in the first to fourth subfields are respectively A+a, B+b, C+c and D+d, wherein a, b, c and d are respectively a time difference between times for lighting pixels of corresponding subfields in two frames. The time difference may be a positive value or a negative value, or may be zero. These time differences may be calculated when a frame of image is divided, and the reference time may be calculated at the same time.

As shown in FIG. 5c, in a (N+1)^{th} frame of image, lighting times for a pixel in the first to fourth subfields are respectively A+a′, B+b′, C+C and D+d′, wherein a′, b′, c′ and d′ are respectively a time difference between times for lighting pixels of corresponding subfields in two frames, which may be a positive value or a negative value, or may be zero.

In an embodiment of the present disclosure, the minor adjustment value is smaller than the subfield reference time taken as the reference time of a corresponding subfield of the frame of image. Specifically, as shown in FIGS. 5a-5c, since the above a, b, c and d, a′, b′, c′ and d′ are minor adjustment values for the subfields, they are smaller than the corresponding reference times A, B, C and D. That is, a<A, b<B, c<C, d<D, a′<A, b′<B, c′<C and d′<D.

In order to ensure that the entire displayed image will have a constant brightness, in an embodiment of the present disclosure, minor adjustment values satisfy the following condition:

Σₙ₌₁^{N}(a₁+a₂+ . . . +a_{N})=0 (1)

wherein, a₁, a₂ . . . a_{N} represent minor adjustment values over subfield reference times for corresponding subfields in the first, second, . . . , N^{th} frame of images, and N is the number of the frames of images. Specifically, for the first to the N^{th} frames, the minor adjustment value for a subfield bit4 in the first frame of image is a₁. The minor adjustment value for a subfield bit4 in the second frame of image is a₂. The minor adjustment value for a subfield bit4 in the third frame of image is a₃ . . . . The minor adjustment value for a subfield bit4 in the N^{th} frame of image is a_{N}, a₁, a₂ . . . a_{N} satisfy the equation (1).

In an embodiment of the present disclosure, at the same time each subfield is changed dynamically by adjusting time for lighting the subfield, the distribution of the subfields in the frame of image is adjusted to smooth the displayed gray-scales. Specifically, as shown in FIGS. 5a-5c, the subfields in each frame of image are outputted in an order of bit4-bit1, such that the entire frame of image is arranged according to the order of bit4-bit1. In the present disclosure, the entire frame may be outputted according to the order of bit4, bit2, bit3 and bit1 or according to other orders. The subfields are distributed in the entire frame of image. Thus, it can also eliminate flicker images and improve the image display effect.

In an embodiment of the present disclosure, adjusting the distribution of the subfields in the same frame of image by adjusting the output order of the subfields in the same frame of image may further include: setting the output orders of the subfields in two adjacent frames of images to be the same. Specifically, for example, both of the adjacent frames of images may output the subfields according to an order of bit4, bit2, bit3 and bit1 or according to other fixed orders.

In an embodiment of the present disclosure, adjusting the distribution of the subfields in the same frame of image by adjusting the output order of the subfields in the same frame of image may further include: setting the output orders of the subfields in two adjacent frames of images to be different. Specifically, as shown in FIG. 6, a previous frame of image outputs subfields according to an order of bit4, bit3, bit2 and bit1, a next frame of image outputs subfields according to an order of bit4, bit2, bit3 and bit1, and a further next frame of image outputs subfields according to another order.

In view of the above, the order for outputting the subfields may be with or without an order, and two adjacent frames of images may have the same or different subfield output orders. It may be decided with a predetermined data processing rule. Although the subfield output order may be changed, the total amount of light in the frame of image is controlled constant. The time length for lighting each subfield may be different. The number of subfields into which the image is to be divided is not limited, as long as the numbers of subfields divided for two adjacent frames are the same. The present disclosure is not limited to an OLED PWM display driving, and is also applicable for other digital driving.

In the present disclosure, each subfield is changed dynamically by adjusting time length for lighting the subfield, so that the displayed gray-scales by PWM OLED can be smoother, the displayed image can be better, and the problem of flicker images and step effects in displayed gray-scales in the existing OLED PWM driving design solution can be eliminated.

The above description should not be construed as limitations of the present disclosure, but merely as exemplifications of preferred embodiments thereof. Any variations or replacements that can be readily envisioned by those skilled in the art are intended to be within the scope of the present disclosure. Hence, the scope of the present disclosure should be subject to the scope defined in the claims.

1. An OLED PWM driving method, comprising:
dividing each input frame of image into an equal number of subfields with a same size; and
changing each subfield dynamically by adjusting a time for lighting the subfield, such that the gray-scales displayed become smoother.

2. The method according to claim 1, wherein changing each subfield dynamically by adjusting the time for lighting the subfield further comprises:
determining a subfield reference time for lighting pixels in each subfield after the frame of image is divided; and
adding a corresponding minor adjustment value on the subfield reference time for lighting pixels in each subfield, to adjust the time length for lighting the subfield.

3. The method according to claim 2, wherein the subfield reference time is a time for lighting pixels in a subfield of any frame of image.

4. The method according to claim 3, wherein the minor adjustment value is a time difference between a time for lighting pixels in a subfield of a frame of image, and a time for lighting pixels in a corresponding subfield of a frame of image, which is taken as the subfield reference time.

5. The method according to claim 4, wherein the minor adjustment value is smaller than the subfield reference time taken as the reference time of a corresponding subfield of the frame of image.

6. The method according to claim 3, wherein the minor adjustment values satisfy:
Σₙ₌₁^{N}(a₁+a₂+ . . . +a_{N})=0
wherein, a₁, a₂ . . . a_{N} represents minor adjustment values over subfield reference times for corresponding subfields in the first, second, . . . , N^{th} frame of images, and N is the number of the frames of images.

7. The method according to claim 4, wherein the minor adjustment values satisfy:
Σₙ₌₁^{N}(a₁+a₂+ . . . +a_{N})=0
wherein, a₁, a₂ . . . a_{N} represents minor adjustment values over subfield reference times for corresponding subfields in the first, second, . . . , N^{th} frame of images, and N is the number of the frames of images.

8. The method according to claim 5, wherein the minor adjustment values satisfy:
Σₙ₌₁^{N}(a₁+a₂+ . . . +a_{N})=0
wherein, a₁, a₂ . . . a_{N} represents minor adjustment values over subfield reference times for corresponding subfields in the first, second, . . . , N^{th} frame of images, and N is the number of the frames of images.

9. The method according to claim 1, wherein at the same time each subfield is changed dynamically by adjusting time for lighting the subfield, the distribution of the subfields in the frame of image is adjusted to smooth the displayed gray-scales.

10. The method according to claim 9, wherein by adjusting an output order of the subfields in the same frame of image, the distribution of the subfields in the same frame of image is adjusted.

11. The method according to claim 10, wherein adjusting the distribution of the subfields in the same frame of image by adjusting the output order of the subfields in the same frame of image further comprises: setting the output orders of the subfields in two adjacent frames of images to be the same.

12. The method according to claim 10, wherein adjusting the distribution of the subfields in the same frame of image by adjusting the output order of the subfields in the same frame of image further comprises: setting the output orders of the subfields in two adjacent frames of images to be different.
